(19) United States
(12) Patent Application Publication
(10) Pub. No.: US 2005/0135144 A1
(43) Pub. Date: Jun. 23, 2005

(54) Molecular switching device

(76) Inventors: Sung Yool Choi, Daejeon-city (KR); Chan Woo Park, Daejeon-city (KR); Sangouk Ryu, Daejeon-city (KR); Han Young Yu, Daejeon-city (KR); Ung Hwan Pi, Daejeon-city (KR); Taehyoung Zyung, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/863,413

(22) Filed: Jun. 7, 2004

(30) Foreign Application Priority Data
Dec. 23, 2003 (KR) 2003-95391

(51) Int. Cl. G11C 11/00

(52) U.S. Cl. 365/151

(57) ABSTRACT

A molecular switching device including: a channel unit which constructs an electron channel for allowing electron to flow therethrough; an electrode which is in contact with both ends of the channel unit; and a control unit which is connected with the channel unit through a connection unit to have an oxidation state or an electron density differentiated depending on voltage applied through the electrode, thereby varying an electric conductivity of the channel unit.

### BACKGROUND OF THE INVENTION

This application claims the priority of Korean Patent Application No. 2003-95391, filed on Dec. 23, 2003, in the Korean Intellectual Property Office, the disclosure of which is incorporated herein in its entirety by reference.

1. Field of the Invention

The present invention relates to a molecular switching device.

2. Description of the Related Art

Generally, a molecular switching device uses organic molecule or inorganic molecule as an electron channel. The molecular switching device is being noticed as an alternative for overcoming an integration limit of a conventional semiconductor device.

The conventional molecular switching device uses a principle that its molecular structure is changed depending on an oxidation state of catenane, rotaxane or the like so that a resistance difference is caused. Accordingly, the conventional molecular switching device has a drawback in that the change of the molecular structure makes it difficult to operate at a high speed below 10 microsecond (μs), and a switching effect is reduced after several cycles due to a fatigue phenomenon of a molecular film.

### SUMMARY OF THE INVENTION

The present invention provides a molecular switching device, which can be switched by an electric signal to perform a high speed operation.

According to an aspect of the present invention, there is provided a molecular switching device including: a channel unit which constructs an electron channel for allowing electron to flow therethrough; an electrode which is in contact with both ends of the channel unit; and a control unit which is connected with the channel unit through a connection unit to have an oxidation state or an electron density differentiated depending on voltage applied through the electrode, thereby varying an electric conductivity of the channel unit.

The channel unit may be of carbon nanotubes, semiconducting nanowire, metallic nanowire, high molecular nanofiber or conductive organic molecule. The control unit may be of electron-withdrawing molecules having a strong electron affinity. The electrode may be of a metal of Au, Ag, Cu, Al, Pt or Pd, or be of a highly doped semiconductor, for example, Si or GaAs. The connection unit may be of a nanometer-sized material for physically or chemically connecting the channel unit with the control unit.

Since the external voltage controls the electron state of the control unit, the inventive molecular switching device can increase the switching speed. Further, the inventive molecular switching device uses the structural stable molecule, thereby preventing the switching characteristic from being deteriorated due to the fatigue phenomenon.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram illustrating a structure of a molecular switching device according to a preferred embodiment of the present invention; and

FIG. 2 is a current-voltage graph illustrating an operation of a molecular switching device according to a preferred embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity.

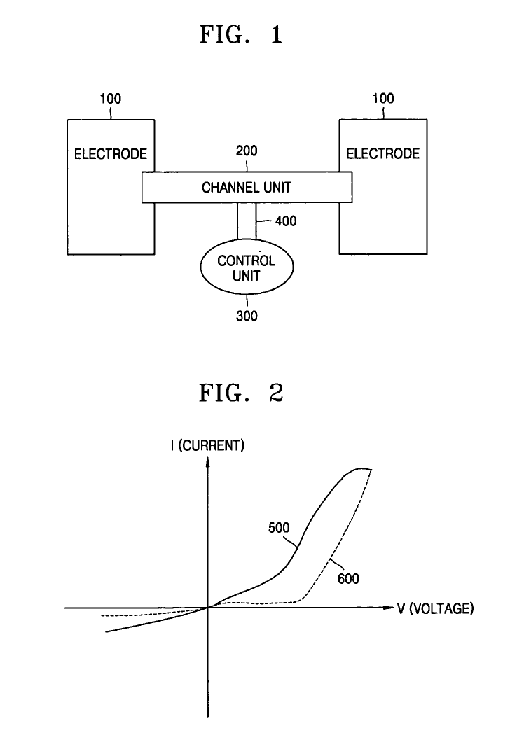

FIG. 1 is a schematic diagram illustrating a structure of a molecular switching device according to a preferred embodiment of the present invention.

In detail, a molecular switching device shown in FIG. 1 includes a channel unit 200 for constructing an electron channel for allowing electron to flow therethrough; an electrode 100 being in contact with both ends of the channel unit 200; and a control unit 300 connected with the channel unit 200 through a connection unit 400 to have an oxidation state or an electron density that is differentiated depending on voltage applied through the electrode 100, thereby varying an electric conductivity of the channel unit 200. In the inventive molecular switching device, the channel unit 200, the connection unit 400 and the control unit 300 can have sizes in nanometer range to be used for manufacturing a highly integrated nano-circuit.

In the molecular switching device, an external voltage applied through the electrode 100 causes the oxidation state or the electron density of the control unit 300 to be differentiated, thereby controlling an electron stream of the channel unit 200 connected to the control unit 300. Specifically, since an electron state of the control unit 300 is controlled under the external voltage, the inventive molecular switching device can increase a switching speed to overcome a limitation of a low speed operation of the conventional molecular switching device.

The channel unit 200 can use all materials having a characteristic of one-dimensional electron transportation such as carbon nanotubes, semiconducting nanowire, metallic nanowire, high molecular nanofiber and conductive organic molecule. A predetermined electric current can flow through the channel unit 200 depending on the applied voltage. The channel unit 200 may use a material having a semiconductive property so as to enhance the switching effect.

The control unit 300 is provided with a stable structure at a predetermined position of the channel unit 200 through the connection unit 400 that is chemically or physically bonded with the channel unit 200. The control unit 300 is formed of a material with the oxidation state or the electron density differentiated due to an external environmental factor. In the inventive molecular switching device, molecule constituting the control unit 300 is structurally stable to prevent a switching characteristic from being deteriorated due to the fatigue phenomenon.

The control unit 300 can be comprised of electron-withdrawing molecules having a strong electron affinity. Specifically, the control unit 300 can use the electron-withdrawing molecule having the strong electron affinity of about 1-4 eV. The electron-withdrawing molecule constituting the control unit 300 may use Tetracyanoquinonedimethane (TCNQ), Tetracyanoanthraquinodimethane (TCNaQ), Tetracyanoethylene (TCNE), 2,3,5,6-tetrafluoro-7,7,8,8-tetracyanoquinodimethane (TCNQF₄), Dicyanoquinodiimine (DCNQI), Trinitrofluorenone, p-Benzonquinone, Dichlorodicyanobenzoquinone (DDQ), Dinitrobenzene, C₆₀ and the like, but can also use other kinds of the electron-withdrawing molecule.

The connection unit 400 is formed of a nanometer-sized material for physically or chemically connecting the channel unit 200 with the control unit 300. The connection unit 400 may substantially use a chemical bond having a low electric conductivity such as alkyl chain.

The electrode 100 being in contact with both ends of the channel unit 200 uses a metal such as Au, Ag, Cu, Al, Pt and Pd, or uses a highly doped semiconductor, for example, Si or GaAs.

FIG. 2 is a current-voltage graph illustrating an operation of the molecular switching device according to a preferred embodiment of the present invention.

In detail, the molecular switching device have the switching effect since the electric current can flow in a predetermined direction when the voltage is applied to the electrode 100 and a high conductance state 500 and a low conductance state 600 can be provided depending on the oxidation state or the electron density of the control unit (300 of FIG. 1).

In particular, the inventive molecular switching device can allow the high speed operation since a channel characteristic is varied from the high conductance state to the low conductance state, and vice versa, depending on a speed at which the external voltage is applied. Further, the inventive molecular switching device can be employed in a nonvolatile memory device since the high conductance state and the low conductance state are maintained for a predetermined period if the control unit (300 of FIG. 1) uses the material for allowing the oxidation state to be changed.

As described above, since the inventive molecular switching device is comprised of the nanometer-sized channel unit and control unit, it can be used in manufacturing the highly integrated nano-circuit. Further, since the external voltage controls the electron state of the control unit, the inventive molecular switching device can increase the switching speed to overcome the limitation of the low speedy operation of the conventional molecular switching device, and can use the structural stable molecule, thereby preventing the switching characteristic from being deteriorated due to the fatigue phenomenon.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A molecular switching device comprising:
a channel unit which constructs an electron channel for allowing electron to flow therethrough;
an electrode which is in contact with both ends of the channel unit; and
a control unit which is connected with the channel unit through a connection unit to have an oxidation state or an electron density differentiated depending on voltage applied through the electrode, thereby varying an electric conductivity of the channel unit.

2. The molecular switching device of claim 1, wherein the channel unit is of carbon nanotubes, semiconducting nanowire, metallic nanowire, high molecular nanofiber or conductive organic molecule.

3. The molecular switching device of claim 1, wherein the control unit is of electron-withdrawing molecules having a strong electron affinity.

4. The molecular switching device of claim 3, wherein the electron-withdrawing molecule is of TCNQ (Tetracyanoquinonedimethane), TCNaQ (Tetracyanoanthraquinodimethane), TCNE (Tetracyanoethylene), TCNQF₄ (2,3,5,6-tetrafluoro-7,7,8,8-tetracyanoquinodimethane), DCNQI (Dicyanoquinodiimine), Trinitrofluorenone, p-Benzonquinone, DDQ (Dichlorodicyanobenzoquinone), Dinitrobenzene, or C₆₀.

5. The molecular switching device of claim 1, wherein the electrode is of a metal of Au, Ag, Cu, Al, Pt or Pd.

6. The molecular switching device of claim 1, wherein the electrode is of a highly doped semiconductor.

7. The molecular switching device of claim 1, wherein the connection unit is of a nanometer-sized material for physically or chemically connecting the channel unit with the control unit.
